(19) United States
(12) Patent Application Publication
(10) Pub. No.: US 2005/0250258 A1
(43) Pub. Date: Nov. 10, 2005

(54) Method for making a semiconductor device having a high-k gate dielectric layer and a metal gate electrode

(76) Inventors: Matthew V. Metz, Hillsboro, OR (US); Suman Datta, Beaverton, OR (US); Jack Kavalieros, Portland, OR (US); Mark L. Doczy, Beaverton, OR (US); Justin K. Brask, Portland, OR (US); Robert S. Chau, Beaverton, OR (US)

Correspondence Address: INTEL CORPORATION, P.O. BOX 5326, SANTA CLARA, CA, 95056-5326, US

(21) Appl. No.: 10/839,077

(22) Filed: May 4, 2004

(51) Int. Cl. H01L 21/335

(52) U.S. Cl. 438/142

(57) ABSTRACT

A method for making a semiconductor device is described. That method comprises forming a high-k gate dielectric layer on a substrate, and forming a masking layer on a first part of the high-k gate dielectric layer. After forming a first metal layer on the masking layer and on an exposed second part of the high-k gate dielectric layer, the masking layer is removed. A second metal layer is then formed on the first metal layer and on the first part of the high-k gate dielectric layer.

### FIELD OF THE INVENTION

The present invention relates to methods for making semiconductor devices, in particular, semiconductor devices that include metal gate electrodes.

### BACKGROUND OF THE INVENTION

MOS field-effect transistors with very thin gate dielectrics made from silicon dioxide may experience unacceptable gate leakage currents. Forming the gate dielectric from certain high-k dielectric materials, instead of silicon dioxide, can reduce gate leakage. Because, however, such a dielectric may not be compatible with polysilicon, it may be desirable to use metal gate electrodes in devices that include high-k gate dielectrics.

When making a CMOS device that includes metal gate electrodes, a replacement gate process may be used to form gate electrodes from different metals. In that process, a first polysilicon layer, bracketed by a pair of spacers, is removed to create a trench between the spacers. The trench is filled with a first metal. A second polysilicon layer is then removed, and replaced with a second metal that differs from the first metal. Because this process requires multiple etch, deposition, and polish steps, high volume manufacturers of semiconductor devices may be reluctant to use it.

Rather than apply a replacement gate process to form a metal gate electrode on a high-k gate dielectric layer, a subtractive approach may be used. In such a process, a metal gate electrode is formed on a high-k gate dielectric layer by depositing a metal layer on the dielectric layer, masking the metal layer, and then removing the uncovered part of the metal layer and the underlying portion of the dielectric layer. Unfortunately, the exposed sidewalls of the resulting high-k gate dielectric layer render that layer susceptible to lateral oxidation, which may adversely affect its physical and electrical properties. Furthermore, not all metal gate electrode materials are compatible with the subtractive process flow.

Accordingly, there is a need for an improved process for making a semiconductor device that includes a high-k gate dielectric layer and a metal gate electrode. There is a need for such a process that may be suitable for high volume manufacturing. The method of the present invention provides such a process.

### BRIEF DESCRIPTION OF THE DRAWINGS

FIGS. 1a-1i represent cross-sections of structures that may be formed when carrying out an embodiment of the method of the present invention.

FIGS. 2a-2h represent cross-sections of structures that may be formed when carrying out a second embodiment of the method of the present invention.

Features shown in these figures are not intended to be drawn to scale.

### DETAILED DESCRIPTION OF THE PRESENT INVENTION

A method for making a semiconductor device is described. That method comprises forming a high-k gate dielectric layer on a substrate, then forming a masking layer on a first part of the high-k gate dielectric layer. After forming a first metal layer on the masking layer and on an exposed second part of the high-k gate dielectric layer, the masking layer is removed and a second metal layer is formed on the first metal layer and on the first part of the high-k gate dielectric layer. In the following description, a number of details are set forth to provide a thorough understanding of the present invention. It will be apparent to those skilled in the art, however, that the invention may be practiced in many ways other than those expressly described here. The invention is thus not limited by the specific details disclosed below.

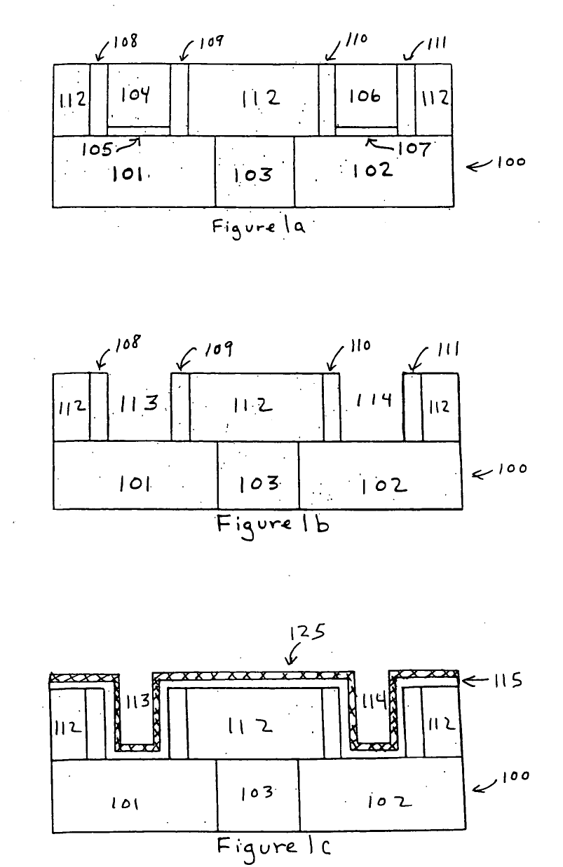

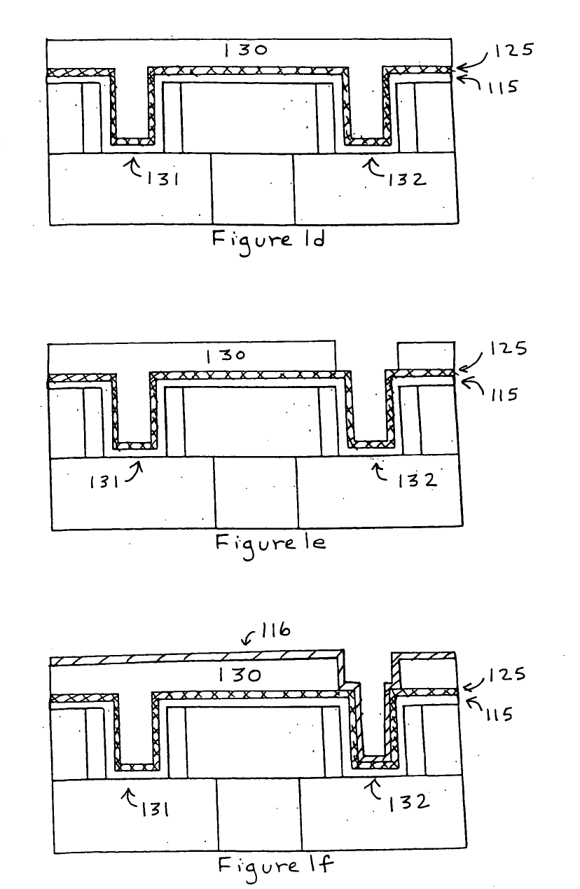

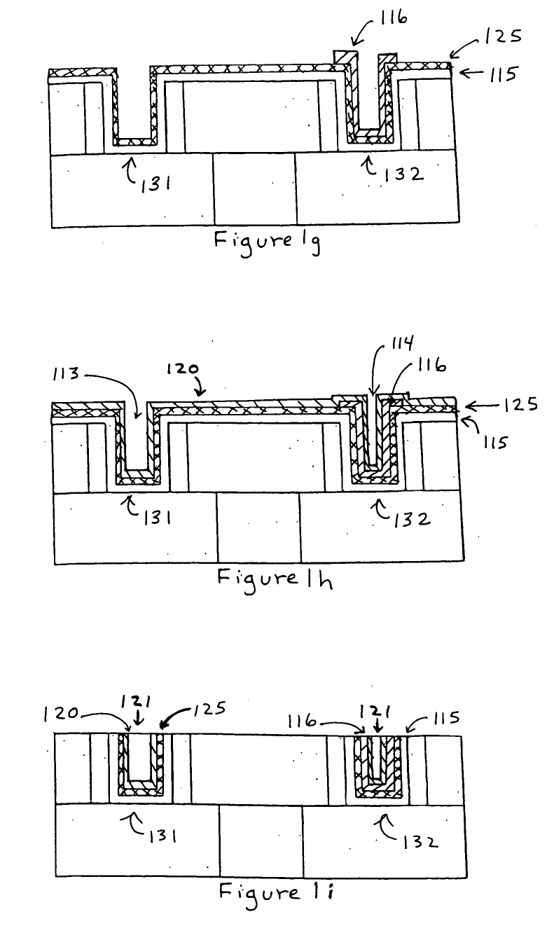

FIGS. 1a-1i illustrate structures that may be formed, when carrying out an embodiment of the method of the present invention in a replacement gate process. FIG. 1a represents an intermediate structure that may be formed when making a CMOS device. That structure includes first part 101 and second part 102 of substrate 100. Isolation region 103 separates first part 101 from second part 102. First polysilicon layer 104 is formed on dielectric layer 105, and second polysilicon layer 106 is formed on dielectric layer 107. First polysilicon layer 104 is bracketed by a pair of sidewall spacers 108, 109, and second polysilicon layer 106 is bracketed by a pair of sidewall spacers 110, 111. Dielectric 112 lies next to the sidewall spacers.

Substrate 100 may comprise a bulk silicon or silicon-on-insulator substructure. Alternatively, substrate 100 may comprise other materials—which may or may not be combined with silicon—such as: germanium, indium antimonide, lead telluride, indium arsenide, indium phosphide, gallium arsenide, or gallium antimonide. Although a few examples of materials from which substrate 100 may be formed are described here, any material that may serve as a foundation upon which a semiconductor device may be built falls within the spirit and scope of the present invention.

Isolation region 103 may comprise silicon dioxide, or other materials that may separate the transistor's active regions. Dielectric layers 105, 107 may each comprise silicon dioxide, or other materials that may insulate the substrate from other substances. First and second polysilicon layers 104, 106 preferably are each between about 100 and about 2,000 angstroms thick, and more preferably between about 500 and about 1,600 angstroms thick. Those layers each may be undoped or doped with similar substances. Alternatively, one layer may be doped, while the other is not doped, or one layer may be doped n-type (e.g., with arsenic, phosphorus or another n-type material), while the other is doped p-type (e.g., with boron or another p-type material). Spacers 108, 109, 110, 111 preferably comprise silicon nitride, while dielectric 112 may comprise silicon dioxide, or a low-k material. Dielectric 112 may be doped with phosphorus, boron, or other elements, and may be formed using a high density plasma deposition process.

Conventional process steps, materials, and equipment may be used to generate the FIG. 1a structure, as will be apparent to those skilled in the art. As shown, dielectric 112 may be polished back, e.g., via a conventional chemical mechanical polishing (“CMP”) operation, to expose first and second polysilicon layers 104, 106. Although not shown, the FIG. 1a structure may include many other features (e.g., a silicon nitride etch stop layer, source and drain regions, and one or more buffer layers) that may be formed using conventional processes.

When source and drain regions are formed using conventional ion implantation and anneal processes, it may be desirable to form a hard mask on polysilicon layers 104, 106—and an etch stop layer on the hard mask—to protect layers 104, 106 when the source and drain regions are covered with a silicide. The hard mask may comprise silicon nitride, and the etch stop layer may comprise a material that will be removed at a substantially slower rate than silicon nitride will be removed when an appropriate etch process is applied. Such an etch stop layer may, for example, be made from silicon, an oxide (e.g., silicon dioxide or hafnium dioxide), or a carbide (e.g., silicon carbide).

Such an etch stop layer and silicon nitride hard mask may be polished from the surface of layers 104, 106, when dielectric layer 112 is polished—as those layers will have served their purpose by that stage in the process. FIG. 1a represents a structure in which any hard mask or etch stop layer, which may have been previously formed on layers 104, 106, has already been removed from the surface of those layers. When ion implantation processes are used to form the source and drain regions, layers 104, 106 may be doped at the same time the source and drain regions are implanted. In such a process, first polysilicon layer 104 may be doped n-type, while second polysilicon layer 106 is doped p-type—or vice versa.

After forming the FIG. 1a structure, first and second polysilicon layers 104, 106 are removed. In a preferred embodiment, those layers are removed by applying a wet etch process, or processes. Such a wet etch process may comprise exposing layers 104, 106 to an aqueous solution that comprises a source of hydroxide for a sufficient time at a sufficient temperature to remove substantially all of those layers. That source of hydroxide may comprise between about 2 and about 30 percent ammonium hydroxide or a tetraalkyl ammonium hydroxide, e.g., tetramethyl ammonium hydroxide (“TMAH”), by volume in deionized water.

An n-type polysilicon layer may be removed by exposing it to a solution, which is maintained at a temperature between about 15° C. and about 90° C. (and preferably below about 40° C.), that comprises between about 2 and about 30 percent ammonium hydroxide by volume in deionized water. During that exposure step, which preferably lasts at least one minute, it may be desirable to apply sonic energy at a frequency of between about 10 KHz and about 2,000 KHz, while dissipating at between about 1 and about 10 watts/cm². For example, an n-type polysilicon layer that is about 1,350 angstroms thick may be removed by exposing it at about 25° C. for about 30 minutes to a solution that comprises about 15 percent ammonium hydroxide by volume in deionized water, while applying sonic energy at about 1,000 KHz—dissipating at about 5 watts/cm².

As an alternative, an n-type polysilicon layer may be removed by exposing it for at least one minute to a solution, which is maintained at a temperature between about 60° C. and about 90° C., that comprises between about 20 and about 30 percent TMAH by volume in deionized water, while applying sonic energy. Substantially all of such an n-type polysilicon layer that is about 1,350 angstroms thick may be removed by exposing it at about 80° C. for about 2 minutes to a solution that comprises about 25 percent TMAH by volume in deionized water, while applying sonic energy at about 1,000 KHz—dissipating at about 5 watts/cm².

A p-type polysilicon layer may also be removed by exposing it to a solution that comprises between about 20 and about 30 percent TMAH by volume in deionized water for a sufficient time at a sufficient temperature (e.g., between about 60° C. and about 90° C.), while applying sonic energy. Those skilled in the art will recognize that the particular wet etch process, or processes, that should be used to remove first and second polysilicon layers 104, 106 will vary, depending upon whether none, one or both of those layers are doped, e.g., one layer is doped n-type and the other p-type.

For example, if layer 104 is doped n-type and layer 106 is doped p-type, it may be desirable to first apply an ammonium hydroxide based wet etch process to remove the n-type layer followed by applying a TMAH based wet etch process to remove the p-type layer. Alternatively, it may be desirable to simultaneously remove layers 104, 106 with an appropriate TMAH based wet etch process.

After removing first and second polysilicon layers 104, 106, dielectric layers 105, 107 are exposed. In this embodiment, layers 105, 107 are removed. When dielectric layers 105, 107 comprise silicon dioxide, they may be removed using an etch process that is selective for silicon dioxide. Such an etch process may comprise exposing layers 105, 107 to a solution that includes about 1 percent HF in deionized water. The time layers 105, 107 are exposed should be limited, as the etch process for removing those layers may also remove part of dielectric layer 112. With that in mind, if a 1 percent HF based solution is used to remove layers 105, 107, the device preferably should be exposed to that solution for less than about 60 seconds, and more preferably for about 30 seconds or less. As shown in FIG. 1b, removal of dielectric layers 105, 107 leaves trenches 113, 114 within dielectric layer 112 positioned between sidewall spacers 108, 109, and sidewall spacers 110, 111 respectively.

After removing dielectric layers 105, 107, dielectric layer 115 is formed on substrate 100. Preferably, dielectric layer 115 comprises a high-k gate dielectric layer. Some of the materials that may be used to make such a high-k gate dielectric layer include: hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. Particularly preferred are hafnium oxide, zirconium oxide, and aluminum oxide. Although a few examples of materials that may be used to form a high-k gate dielectric layer are described here, that layer may be made from other materials.

High-k gate dielectric layer 115 may be formed on substrate 100 using a conventional deposition method, e.g., a conventional chemical vapor deposition (“CVD”), low pressure CVD, or physical vapor deposition (“PVD”) process. Preferably, a conventional atomic layer CVD process is used. In such a process, a metal oxide precursor (e.g., a metal chloride) and steam may be fed at selected flow rates into a CVD reactor, which is then operated at a selected temperature and pressure to generate an atomically smooth interface between substrate 100 and high-k gate dielectric layer 115. The CVD reactor should be operated long enough to form a layer with the desired thickness. In most applications, high-k gate dielectric layer 115 should be less than about 60 angstroms thick, and more preferably between about 5 angstroms and about 40 angstroms thick.

As shown in FIG. 1c, when an atomic layer CVD process is used to form high-k gate dielectric layer 115, that layer will form on the sides of trenches 113, 114 in addition to forming on the bottom of those trenches. If high-k gate dielectric layer 115 comprises an oxide, it may manifest oxygen vacancies at random surface sites and unacceptable impurity levels, depending upon the process used to make it. It may be desirable to remove impurities from layer 115, and to oxidize it to generate a layer with a nearly idealized metal:oxygen stoichiometry, after layer 115 is deposited.

To remove impurities from that layer and to increase that layer's oxygen content, a wet chemical treatment may be applied to high-k gate dielectric layer 115. Such a wet chemical treatment may comprise exposing high-k gate dielectric layer 115 to a solution that comprises hydrogen peroxide at a sufficient temperature for a sufficient time to remove impurities from high-k gate dielectric layer 115 and to increase the oxygen content of high-k gate dielectric layer 115. The appropriate time and temperature at which high-k gate dielectric layer 115 is exposed may depend upon the desired thickness and other properties for high-k gate dielectric layer 115.

When high-k gate dielectric layer 115 is exposed to a hydrogen peroxide based solution, an aqueous solution that contains between about 2% and about 30% hydrogen peroxide by volume may be used. That exposure step should take place at between about 15° C. and about 40° C. for at least about one minute. In a particularly preferred embodiment, high-k gate dielectric layer 115 is exposed to an aqueous solution that contains about 6.7% H₂O₂ by volume for about 10 minutes at a temperature of about 25° C. During that exposure step, it may be desirable to apply sonic energy at a frequency of between about 10 KHz and about 2,000 KHz, while dissipating at between about 1 and about 10 watts/cm². In a preferred embodiment, sonic energy may be applied at a frequency of about 1,000 KHz, while dissipating at about 5 watts/cm².

Although not shown in FIG. 1c, it may be desirable to form a capping layer, which is no more than about five monolayers thick, on high-k gate dielectric layer 115. Such a capping layer may be formed by sputtering one to five monolayers of silicon, or another material, onto the surface of high-k gate dielectric layer 115. The capping layer may then be oxidized, e.g., by using a plasma enhanced chemical vapor deposition process or a solution that contains an oxidizing agent, to form a capping dielectric oxide.

Although in some embodiments it may be desirable to form a capping layer on high-k gate dielectric layer 115, in the illustrated embodiment, underlayer metal 125 is formed directly on layer 115 to generate the FIG. 1c structure. Underlayer metal 125 may comprise any conductive material from which a metal gate electrode may be derived, and may be formed on high-k gate dielectric layer 115 using well known PVD or CVD processes. Examples of n-type materials that may be used to form underlayer metal 125 include: hafnium, zirconium, titanium, tantalum, aluminum, and metal carbides that include these elements, i.e., titanium carbide, zirconium carbide, tantalum carbide, hafnium carbide and aluminum carbide. Examples of p-type metals that may be used include: ruthenium, palladium, platinum, cobalt, nickel, and conductive metal oxides, e.g., ruthenium oxide.

Although a few examples of materials that may be used to form underlayer metal 125 are described here, that layer may be made from many other materials. Underlayer metal 125 may have approximately the same thickness as high-k gate dielectric layer 115. After forming underlayer metal 125 on high-k gate dielectric layer 115, masking layer 130 is formed on underlayer metal 125, as FIG. 1d illustrates. Masking layer 130 may comprise conventional masking materials and may be formed using conventional process steps. When initially formed, masking layer 130 covers both first part 131 and second part 132 of high-k gate dielectric layer 115. Masking layer 130 is removed where it covers second part 132 of high-k gate dielectric layer 115, but retained where it covers first part 131 of high-k gate dielectric layer 115, generating the FIG. 1e structure. Conventional process steps may be used to remove part of masking layer 130.

First metal layer 116, which may comprise one or more of the previously identified metals, is then formed on masking layer 130 and second part 132 of high-k gate dielectric layer 115, e.g., by applying a conventional PVD or CVD process, to generate the FIG. 1f structure. First metal layer 116 should be thick enough to ensure that any material formed on it will not significantly impact its workfunction. Preferably, metal layer 116 is between about 25 angstroms and about 300 angstroms thick, and more preferably is between about 25 angstroms and about 200 angstroms thick. When metal layer 116 comprises an n-type material, layer 116 preferably has a workfunction that is between about 3.9 eV and about 4.2 eV. When metal layer 116 comprises a p-type material, layer 116 preferably has a workfunction that is between about 4.9 eV and about 5.2 eV.

After forming metal layer 116, the remainder of masking layer 130 is removed using conventional process steps. When the remainder of that layer is removed, the sections of first metal layer 116, which had been formed on masking layer 130, are also removed, generating the FIG. 1g structure. In that structure, first metal layer 116 is formed on second part 132 of high-k gate dielectric layer 115, but is not formed on first part 131 of high-k gate dielectric layer 115.

In this embodiment, second metal layer 120 (which may comprise one or more of the previously identified metals) is then formed on first metal layer 116 and on first part 131 of high-k gate dielectric layer 115, as FIG. 1h illustrates. If first metal layer 116 comprises an n-type metal, e.g., one of the n-type metals identified above, then second metal layer 120 preferably comprises a p-type metal, e.g., one of the p-type metals identified above. Conversely, if first metal layer 116 comprises a p-type metal, then second metal layer 120 preferably comprises an n-type metal.

Second metal layer 120 may be formed on high-k gate dielectric layer 115 and first metal layer 116 using a conventional PVD or CVD process, preferably is between about 25 angstroms and about 300 angstroms thick, and more preferably is between about 25 angstroms and about 200 angstroms thick. If second metal layer 120 comprises an n-type material, layer 120 preferably has a workfunction that is between about 3.9 eV and about 4.2 eV. If second metal layer 120 comprises a p-type material, layer 120 preferably has a workfunction that is between about 4.9 eV and about 5.2 eV.

In this embodiment, after depositing second metal layer 120 on layers 116 and 115, the remainder of trenches 113, 114 is filled with a material that may be easily polished, e.g., tungsten, aluminum, titanium, or titanium nitride. Such a trench fill metal, e.g., metal 121, may be deposited over the entire device using a conventional metal deposition process. That trench fill metal may then be polished back, e.g., by applying a conventional CMP step, so that it fills only trenches 113, 114, as shown in 1i.

After removing trench fill metal 121, except where it fills trenches 113, 114, a capping dielectric layer (not shown) may be deposited onto the resulting structure using any conventional deposition process. Process steps for completing the device that follow the deposition of such a capping dielectric layer, e.g., forming the device's contacts, metal interconnect, and passivation layer, are well known to those skilled in the art and will not be described here.

Underlayer metal 125 may comprise a material that differs from those used to make first and second metal layers 116, 120, or may comprise a material like the material used to make either layer 116 or layer 120. Likewise, trench fill metal 121 may comprise a material that differs from those used to make first and second metal layers 116, 120, or may comprise a material like the material used to make either layer 116 or layer 120. Although in a preferred embodiment, underlayer metal 125 is formed on high-k gate dielectric layer 115 prior to forming first metal layer 116 on underlayer metal 125, in alterative embodiments underlayer metal 125 may be omitted.

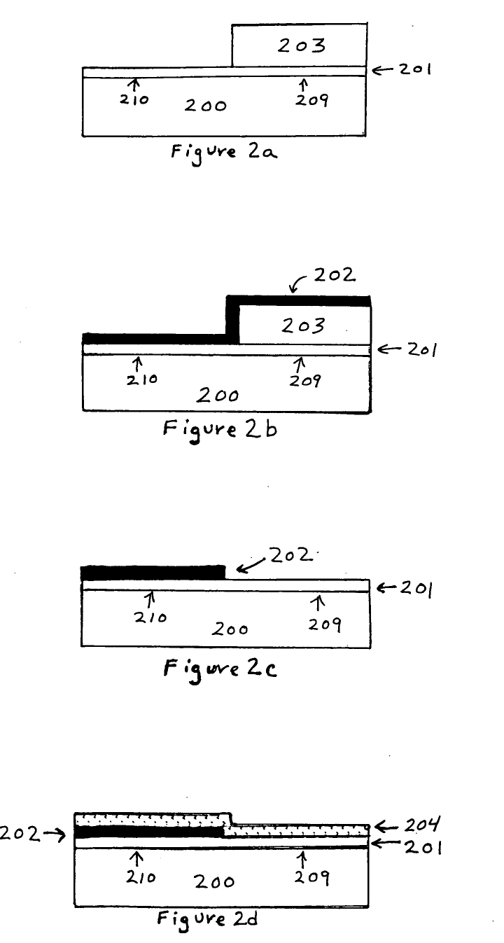

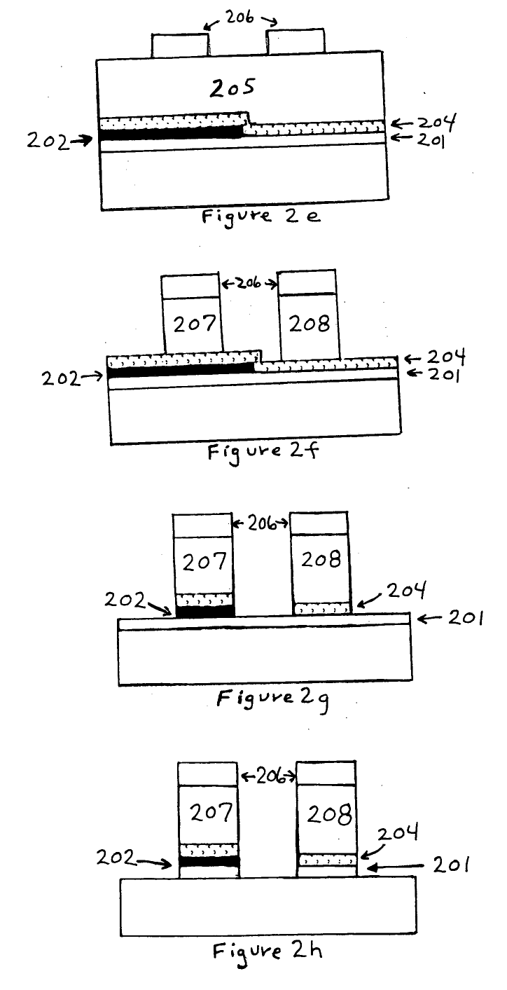

FIGS. 2a-2h represent cross-sections of structures that may be formed when carrying out a second embodiment of the method of the present invention. Unlike the embodiment described above, which applies a replacement gate process to form metal gate electrodes on a high-k gate dielectric layer, this embodiment forms metal gate electrodes on such a dielectric layer using a subtractive process.

Initially, high-k gate dielectric layer 201 is formed on substrate 200. First masking layer 203 is then formed on high-k gate dielectric layer 201, generating the FIG. 2a structure. High-k gate dielectric layer 201 may comprise any of the materials identified above. First masking layer 203 may be formed from conventional materials using conventional techniques, and covers first part 209 of high-k gate dielectric layer 201, but not second part 210 of high-k gate dielectric layer 201.

First metal layer 202 (which may comprise one or more of the previously identified metals) is then formed on first masking layer 203 and on second part 210 of high-k gate dielectric layer 201, e.g., by applying a conventional PVD or CVD process, generating the FIG. 2b structure. First metal layer 202 should be thick enough to ensure that any material formed on it will not significantly impact its workfunction. Preferably, first metal layer 202 is between about 25 angstroms and about 300 angstroms thick, and more preferably is between about 25 angstroms and about 200 angstroms thick. When first metal layer 202 comprises an n-type material, it preferably has a workfunction that is between about 3.9 eV and about 4.2 eV. When first metal layer 202 comprises a p-type material, it preferably has a workfunction that is between about 4.9 eV and about 5.2 eV.

After forming first metal layer 202, first masking layer 203 is removed using conventional process steps. When that layer is removed, the sections of first metal layer 202, which had been formed on first masking layer 203, are also removed, generating the FIG. 2c structure. In that structure, first metal layer 202 is formed on second part 210 of high-k gate dielectric layer 201, but is not formed on first part 209 of high-k gate dielectric layer 201.

In this embodiment, second metal layer 204 (which may comprise one or more of the previously identified metals) is then formed on first metal layer 202 and on first part 209 of high-k gate dielectric layer 201, as FIG. 2d illustrates. If first metal layer 202 comprises an n-type metal, e.g., one of the n-type metals identified above, then second metal layer 204 preferably comprises a p-type metal, e.g., one of the p-type metals identified above. Conversely, if first metal layer 202 comprises a p-type metal, then second metal layer 204 preferably comprises an n-type metal.

Second metal layer 204 may be formed on high-k gate dielectric layer 201 and first metal layer 202 using a conventional PVD or CVD process. Second metal layer 204 should be thick enough to ensure that any material formed on it will not significantly impact its workfunction. Second metal layer 204, like first metal layer 202, preferably is between about 25 angstroms and about 300 angstroms thick, and more preferably is between about 25 angstroms and about 200 angstroms thick. If second metal layer 204 comprises an n-type material, layer 204 preferably has a workfunction that is between about 3.9 eV and about 4.2 eV. If second metal layer 204 comprises a p-type material, layer 204 preferably has a workfunction that is between about 4.9 eV and about 5.2 eV.

After depositing second metal layer 204 on first metal layer 202 and dielectric layer 201, masking layer 205 is deposited on second metal layer 204. Masking layer 206 is then formed on masking layer 205 to define sections of masking layer 205 to be removed and sections to be retained. FIG. 2e represents a cross-section of the structure that results after masking layer 206 is formed on masking layer 205. In a preferred embodiment, masking layer 205 comprises polysilicon, and masking layer 206 comprises silicon nitride or silicon dioxide. After layer 206 is formed, part of layer 205 is removed selective to second metal layer 204, e.g., using a dry etch process, to expose part of layer 204 and to create the FIG. 2f structure. In that structure, second masking layer 207 covers both second metal layer 204 and first metal layer 202, and third masking layer 208 covers only second metal layer 204.

After etching masking layer 205 to form second and third masking layers 207 and 208, the exposed part of second metal layer 204 and the underlying portion of first metal layer 202 are removed, e.g., using a conventional metal etch process, to generate the FIG. 2g structure. After metal layers 204 and 202 are etched, a wet etch process may be applied to remove the exposed part of dielectric layer 201, generating the FIG. 2h structure. Process steps for completing the device that follow that etch step are well known to those skilled in the art, and will not be described in further detail here.

The three layer gate electrode stack of FIG. 2h may serve as the gate electrode for an NMOS transistor with a workfunction between about 3.9 eV and about 4.2 eV, while the two layer gate electrode stack may serve as the gate electrode for a PMOS transistor with a workfunction between about 4.9 eV and about 5.2 eV. Alternatively, the three layer gate electrode stack may serve as the gate electrode for a PMOS transistor, while the two layer gate electrode stack may serve as the gate electrode for an NMOS transistor.

The first metal layer should set the transistor's workfunction, regardless of the composition of the remainder of the gate electrode stack. For that reason, the presence of the second metal layer on top of the first metal layer in the three layer gate electrode stack, and the presence of a dummy doped polysilicon layer in either a three or two layer gate electrode stack, should not affect the workfunction of the gate electrode stack in a meaningful way.

Although such a polysilicon layer should not affect the workfunction of an underlying metal layer, that polysilicon layer may serve as an extension of the transistor's contacts, as well as a support for subsequently formed nitride spacers. It also defines the transistor's vertical dimension. Gate electrode stacks that include such a polysilicon layer are thus considered to be “metal gate electrodes,” as are gate electrode stacks that include one or more metal layers, but do not include a polysilicon layer.

Although not included in this embodiment, an underlayer metal—like the underlayer metal described above—may be formed on the high-k gate dielectric layer prior to forming the first metal layer. That underlayer metal may comprise any of the metals identified above, may be formed using any of the previously described process steps, and may have approximately the same thickness as the high-k gate dielectric layer. The underlayer metal may comprise a material that differs from those used to make the first and second metal layers, or may comprise a material like the material used to make either the first metal layer or the second metal layer.

As illustrated above, the method of the present invention enables production of CMOS devices with a high-k gate dielectric layer and metal gate electrodes with appropriate workfunctions for both NMOS and PMOS transistors. In this method, a first metal layer is formed on only part of a high-k gate dielectric layer, without having to mask—then remove—part of a previously deposited metal layer. Because such a lift off approach eliminates metal patterning and etch steps, it may be easier to integrate into a high volume semiconductor manufacturing process, when compared to other processes for forming metal gate electrodes on a high-k gate dielectric layer. Although the embodiments described above provide examples of processes for forming CMOS devices with a high-k gate dielectric layer and metal gate electrodes, the present invention is not limited to these particular embodiments.

Although the foregoing description has specified certain steps and materials that may be used in the present invention, those skilled in the art will appreciate that many modifications and substitutions may be made. Accordingly, it is intended that all such modifications, alterations, substitutions and additions be considered to fall within the spirit and scope of the invention as defined by the appended claims.

1. A method for making a semiconductor device comprising:
forming a high-k gate dielectric layer on a substrate;
forming a masking layer on a first part of the high-k gate dielectric layer;
forming a first metal layer on the masking layer and on an exposed second part of the high-k gate dielectric layer;
removing the masking layer; then
forming a second metal layer on the first metal layer and on the first part of the high-k gate dielectric layer.

2. The method of claim 1 wherein the high-k gate dielectric layer comprises a material that is selected from the group consisting of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

3. The method of claim 1 wherein the first metal layer comprises a material that is selected from the group consisting of hafnium, zirconium, titanium, tantalum, aluminum, and a metal carbide, and the second metal layer comprises a material that is selected from the group consisting of ruthenium, palladium, platinum, cobalt, nickel, and a conductive metal oxide.

4. The method of claim 1 wherein the first metal layer comprises a material that is selected from the group consisting of ruthenium, palladium, platinum, cobalt, nickel, and a conductive metal oxide and the second metal layer comprises a material that is selected from the group consisting of hafnium, zirconium, titanium, tantalum, aluminum, and a metal carbide.

5. The method of claim 1 wherein the first and second metal layers are each between about 25 and about 300 angstroms thick, the first metal layer has a workfunction that is between about 3.9 eV and about 4.2 eV, and the second metal layer has a workfunction that is between about 4.9 eV and about 5.2 eV.

6. The method of claim 1 wherein the first and second metal layers are each between about 25 and about 300 angstroms thick, the first metal layer has a workfunction that is between about 4.9 eV and about 5.2 eV, and the second metal layer has a workfunction that is between about 3.9 eV and about 4.2 eV.

7. The method of claim 1 further comprising forming an underlayer metal on the high-k gate dielectric layer prior to forming the masking layer on the first part of the high-k gate dielectric layer.

8. A method for making a semiconductor device comprising:
forming a first dielectric layer on a substrate;
forming a trench within the first dielectric layer;
forming a high-k gate dielectric layer on the substrate, the high-k gate dielectric layer having a first part and a second part that is formed at the bottom of the trench;
forming a masking layer on the first part of the high-k gate dielectric layer;
forming a first metal layer on the second part of the high-k gate dielectric layer;
removing the masking layer; then
forming a second metal layer on the first metal layer and on the first part of the high-k gate dielectric layer.

9. The method of claim 8 further comprising forming an underlayer metal on the first part of the high-k gate dielectric layer and on the second part of the high-k gate dielectric layer prior to forming the masking layer on the first part of the high-k gate dielectric layer.

10. The method of claim 8 further comprising forming a fill metal within the trench and on the second metal layer.

11. A method for making a semiconductor device comprising:
forming a high-k gate dielectric layer on a substrate;
forming a first masking layer on a first part of the high-k gate dielectric layer;
forming a first metal layer on the masking layer and on an exposed second part of the high-k gate dielectric layer;
removing the first masking layer;
forming a second metal layer on the first metal layer and on the first part of the high-k gate dielectric layer; and then
forming a second masking layer on the second metal layer.

12. The method of claim 11 wherein the second masking layer comprises polysilicon.

13. The method of claim 11 further comprising etching the second masking layer, the second metal layer, the first metal layer, and the high-k gate dielectric layer after forming the second masking layer on the second metal layer.

14. The method of claim 11 wherein the second masking layer covers both the second metal layer and the first metal layer, and further comprising forming a third masking layer that covers only the second metal layer.

15. The method of claim 11 wherein the first metal layer has a workfunction that differs from the workfunction of the second metal layer.
